(19) United States
(12) Patent Application Publication
(10) Pub. No.: US 2011/0045985 A1
(43) Pub. Date: Feb. 24, 2011

(54) SUPERCONDUCTOR COMPRISING LAMELLAR COMPOUND AND PROCESS FOR PRODUCING THE SAME

(75) Inventors: Hideo Hosono, Kanagawa (JP); Hiroshi Yanagi, Tokyo (JP); Toshio Kamiya, Kanagawa (JP); Satoru Matsuishi, Tokyo (JP); Sungwng Kim, Kanagawa (JP); Seok Gyu Yoon, Kanagawa (JP); Hidenori Hiramatsu, Kanagawa (JP); Masahiro Hirano, Tokyo (JP); Yoichi Kamihara, Tokyo (JP); Takatoshi Nomura, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: JAPAN SCIENCE AND TECHNOLOGY AGENCY, Kawaguchi-shi, Saitama (JP)

(21) Appl. No.: 12/934,931

(22) PCT Filed: Feb. 20, 2009
(86) PCT No.: PCT/JP2009/053062

§ 371 Date: Sep. 27, 2010

(30) Foreign Application Priority Data
Mar. 27, 2008 (JP) 2008-082386

(51) Int. Cl. C22C 30/00; H01L 39/00; H01L 39/24; C22C 30/02

(52) U.S. Cl. 505/121; 505/124; 505/490; 505/492; 420/580; 420/587; 420/581; 419/1; 423/299

(57) ABSTRACT

A superconductor which comprises a new compound composition substituting for perovskite copper oxides. The superconductor is characterized by comprising a compound which is represented by the chemical formula A(TM)₂Pn₂ [wherein A is at least one member selected from the elements in Group 1, the elements in Group 2, or the elements in Group 3 (Sc, Y, and the rare-earth metal elements); TM is at least one member selected from the transition metal elements Fe, Ru, Os, Ni, Pd, or Pt; and Pn is at least one member selected from the elements in Group 15 (pnicogen elements)] and which has an infinite-layer crystal structure comprising (TM)Pn layers alternating with metal layers of the element (A).

### TECHNICAL FIELD

The present invention relates to a superconductor including a lamellar compound having a transition metal element (at least one of Fe, Ru, Os, Ni, Pd, and Pt) in the backbone thereof, and to a process for producing the superconductor.

### BACKGROUND ART

Ever since the discovery of high-temperature superconductors (perovskite copper oxides), research and development of materials has been actively pursued toward the discovery of room-temperature superconductors and superconducting compounds having a critical temperature (Tc) exceeding 100 K have been discovered.

Understanding of the mechanism through which perovskite copper oxides express superconductivity is also growing (for example, refer to non-patent documents 1 and 2). Newly discovered are compounds containing transition metal ions other than copper and novel compounds such as Sr₂RuO₄ (Tc=0.93 K) (non-patent document 3), magnesium diboride (Tc=39 K) (non-patent document 4 and patent document 1), and Na_{0.3}CoO₂.1.3H₂O (Tc=5 K) (non-patent document 5 and patent documents 2 and 3).

It is known that there is a high possibility that a strongly correlated electron system compound having strong conduction electron interactions compared to the conduction band width will turn into a superconductor having a high critical temperature when the number of d electrons is a particular number. A strongly correlated electron system is realized in a lamellar compound having a transition metal ion in the backbone thereof. Many of such lamellar compounds are Mott-insulators in terms of electrical conductivity, and antiferromagnetic interactions that induce antiparallel orientations act on electron spins.

However, for example, La₂CuO₄, which is a perovskite copper oxide, enters an itinerant electron state that exhibits metal conduction when La³⁺ ion sites are doped with Sr²⁺ ions to form La₂₋ₓSrₓCuO₄ with x taking a value of 0.05 to 0.28, and a superconductor state is observed at low temperatures with maximum Tc=40 K when x=0.15 (non-patent document 6).

In 1992, a (Sr₁₋ₓCaₓ)_{1-y}CuO_{2+z} superconductor having a critical temperature Tc=110 K was discovered (non-patent document 7). This superconductor has a simple crystal structure called an “infinite layer structure” constituted by Cu—O₂ faces and (Sr/Ca) layers. This superconductor was first synthesized under an ultra-high pressure; however, presently, it can be synthesized at normal pressures. However, high-pressure synthesis is advantageous since oxygen deficiencies can be controlled.

Recently, the inventors of this application have found a novel strongly correlated electron system compound mainly composed of Fe and that LaOFeP and LaOFeAs are superconductors and filed a patent application therefor (patent document 4). In a strongly correlated electron system, an itinerant electron state exhibiting metal conduction arises when the number of d electrons is a particular value and transition to a superconducting state occurs at a particular temperature (critical temperature Tc) or less when the temperature is lowered. The critical temperature of this superconductor varies from 5 K to 40 K depending on the number of conduction carriers. Moreover, whereas the mechanism through which traditional superconductors such as Hg and Ge₃Nb express superconductivity is believed to be through electron pairs (Cooper pairs) based on heat fluctuations in crystal lattices (lattice vibrations) (BCS mechanism), the mechanism through which superconductivity arises in a strongly correlated electron system is believed to be through electron pairs based on heat fluctuations of electron spins.

[Non-patent Document 1] Nobuo Tsuda, Keiichiro Nasu, Atsushi Fujimori, Kiichi Shiratori, “Electronic Conduction in Oxides” Revised edition, pp. 350 to 452, Shokabo Publishing Co. Ltd. (1993)

### [Non-patent Document 2] Sadamichi Maekawa, Applied Physics Vol. 75, No. 1, pp. 17-25 (2006)

### [Non-patent Document 3] Y. Maeno, H. Hashimoto, K. Yoshida, S. Nishizaki, T. Fujita, J. G. Bednorz, F. Lichenberg, Nature, 372, pp. 532-534, (1994)

### [Non-patent Document 4] J. Nagamatsu, N. Nakagawa, T. Muranaka, Y. Zenitani, J. Akimitsu, Nature, 410, pp. 63-64, (2001)

### [Non-patent Document 5] K. Takada, H. Sakurai, E. Takayama-Muromachi, F. Izumi, R. A. Dilanian, T. Sasaki, Nature, 422, pp. 53-55, (2003)

[Non-patent Document 6] J. B. Torrance et al., Phys. Rev., B40, pp. 8872-8877, (1989)

### [Non-patent Document 7] M. Azuma et al., Nature, 356, (1992), 775

### [Patent Document 1] Japanese Unexamined Patent Application Publication No. 2002-211916

### [Patent Document 2] Japanese Unexamined Patent Application Publication No. 2004-262675

### [Patent Document 3] Japanese Unexamined Patent Application Publication No. 2005-350331

### [Patent Document 4] Japanese Unexamined Patent Application Publication No. 2007-320829

### DISCLOSURE OF INVENTION

### Problems to be Solved by the Invention

In order to dramatically broaden the range of application of superconducting technology, discovery of room-temperature superconductors is strongly desired. High-temperature superconductors having Tc exceeding 100 K have been found among lamellar perovskite copper oxides; however, room-temperature superconductors have not yet been found. One approach for developing room-temperature superconductors is to find a novel lamellar compound group that has a transition metal element in the backbone thereof and that can replace perovskite copper oxides, optimize the material parameters such as electronic density, lattice constant, etc., that will yield high Tc, and discover a chemical composition that realizes this. Moreover, due to recent advancement in helium-circulation freezing technology, superconductors can be used in small magnets, motors, etc., when the material features a large superconducting current, a large critical magnet field, ease of processing into wire, etc.

### Means for Solving the Problems

Previously, the inventors have found a superconductor comprising a strongly correlated electron compound, namely a Ln(TM)OPn compound [where Ln is at least one of Y and rare earth metal elements (La, Ce, Pr, Nd, Sm, Eu, Gd, Tb, Dy, Ho, Er, Tm, Yb, and Lu), TM is at least one of transition metal elements (Fe, Ru, Os, Ni, Pd, and Pt), and Pn is at least one of pnicogen elements (N, P, As, and Sb)], and filed patent application therefor (Japanese Patent Application No. 2008-35977).

The inventors have also realized superconductors from lamellar compounds represented by chemical formula A(TM)₂Pn₂. Element A is at least one selected from group 1, 2, and 3 (Sc, Y, and rare earth metal) elements in the long format periodic table that are not limited in terms of their charges. TM is at least one selected from transition metal elements, namely, Fe, Ru, Os, Ni, Pd, and Pt. Pn is at least one selected from group 15 elements (pnicogen elements) in the long format periodic table.

A compound that forms a superconductor of the present invention has a structure in which (TM)Pn layers and layers composed of metal bonds including element A are alternately stacked. In the (TM)Pn layers, element TM and element Pn are covalently bonded, electrons freely move about between elements, and metal electrical conductivity is exhibited. Electrons that contribute to electric conduction or superconduction are two-dimensionally confined in the (TM)Pn layers. For Cu oxide superconductors, compounds having this structure are called “infinite layer crystal structure compounds”.

When A in chemical formula A(TM)₂Pn₂ is a combination of at least one element of one group selected from group 1, group 2, and group 3 in the long format periodic table and at least one element of a group different from the selected one group, (TM)Pn layers can be doped with electrons or holes.

When A in chemical formula A(TM)₂Pn₂ is a combination of at least two elements of a group selected from group 1, group 2, and group 3 in the long format periodic table, excess electrons or holes occur within the A layers due to the difference in electronegativity, the electrons or holes move to the (TM)Pn layers, and, as a consequence, (TM)Pn forming the conductive layers can be doped with the electrons or holes.

The A(TM)₂Pn₂ crystals contain (TM)Pn layers, which are included in the Ln(TM)OPn crystal structure and exhibit metal electrical conduction that makes important contributions to expression of superconductivity. The (TM)Pn layers have a distorted tetrahedral structure with Pn tetrahedrally coordinated to TM. The (TM)Pn layers are constituted by TM-Pn₄ tetrahedrons that share edges and are lined up. When the type of element A or a combination of at least two elements is appropriately selected, the charges of the (TM)Pn layers, the interlayer distance, the TM-TM distance in the layers, and the distortion of the TM-Pn₄ tetrahedrons can be controlled. These changes affect the electronic state of the (TM)Pn layers and ultimately the superconducting state.

A superconducting state is realized when the magnitude of the magnetic interactions between the d electrons in the (TM)Pn layers is adequate. If the magnetic interactions are excessively strong, a magnetically aligned state results and the superconducting state is not realized. If the magnetic interactions are excessively weak, the normal conduction state persists until low temperatures and the superconducting state is not realized. The magnetic interactions are determined by the magnetic moment of element TM, the number of electrons, the degree of covalent bonding between element TM and element Pn, the magnitude and sign of the magnetic interactions between element TM, the distance between elements, etc.

The superconductor of the present invention can be produced by, for example, a process including sintering a raw material mixed powder in vacuum or in an inert gas atmosphere at 700° C. to 1200° C. to form a sintered material containing, on a weight basis, 85% or more of a compound phase represented by chemical formula A(TM)₂Pn₂.

### ADVANTAGEOUS EFFECTS OF INVENTION

Unlike publicly known superconductors, the superconductors provided by the present invention are of a novel system including pnictide containing a transition metal element. This superconductor has metal mechanical properties and can be easily processed into wires since layers composed of element A are composed of a metal.

### BRIEF DESCRIPTION OF DRAWINGS

FIG. 1 is a model diagram of a crystal structure of a compound (b) and an Ln(TM)OPn compound (a) constituting a superconductor of the present invention.

FIG. 2 is an X-ray diffraction pattern of a sintered material obtained in Example 1.

FIG. 3 is a graph showing changes in electrical resistance of the sintered material obtained in Example 1 versus temperature.

FIG. 4 is a graph showing the change in magnetic susceptibility of the sintered material obtained in Example 1 against temperature and the dependency of the magnetic moment thereof on the magnetic field.

### BEST MODES FOR CARRYING OUT THE INVENTION

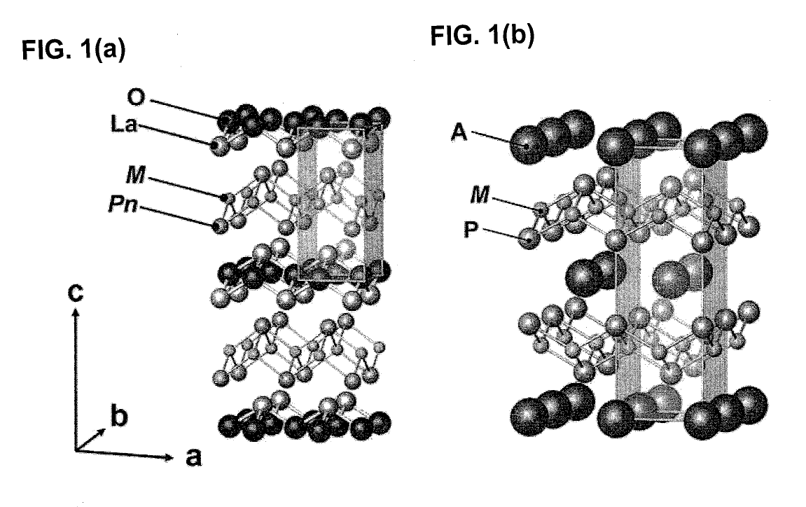

FIG. 1(b) shows a crystal structure model of a lamellar compound represented by A(TM)₂Pn₂, which is the superconductor of the present invention. FIG. 1(a) shows a crystal structure model of a LnTMOPn compound as a comparison. The compound represented by A(TM)₂Pn₂ has a ThCr₂Si₂-type crystal structure in which (TM)Pn layers and metal layers composed of element A are alternately stacked without any insulating layers therebetween. Since only a half of the element A sites are occupied by element A, the chemical formula of the metal layer is A1/2(TM)Pn=A(TM)₂Pn₂. For Cu oxide superconductors, compounds having such a structure have an infinite layer crystal structure and thus are called “infinite layer compounds”; hence the name “infinite layer compounds” is used in this specification.

There are infinite layer structure A(TM)₂Pn₂ compounds that have a tetragonal crystal structure and those that have an orthorhombic crystal structure. In order to process the compound into wires, tetragonal crystals in which two crystal axes in the (TM)Pn layers are equivalent are preferred since the superconducting phases can be made continuous at grain boundaries.

Examples of element A in the compound represented by chemical formula A(TM)₂Pn₂ include group 1 elements such as Na, K, Rb, and Cs, group 2 elements such as Be, Mg, Ca, Sr, and Ba, and group 3 elements such as Sr, Y, and rare earth metals (atomic number 57 to 71). In elements having large atomic numbers, electrons involved in chemical bonding (6s and 6p electrons) have large orbital radii; thus, they are suitable for expressing superconductivity due to large orbital overlap, high electron mobility, and improved electrical conductivity of the metal layer composed of element A. From this viewpoint, Cs, Ba, and La are preferred but Cs has only one electron that is involved in bonding per atom and thus the bond is weak. La has three such electrons and thus the bond is excessively strong. Thus, Ba, which has an intermediate characteristic, is most preferable.

Group 1 elements such as Na, K, Rb, and Cs, group 2 elements such as Mg, Ca, Sr, and Ba, group 3 elements such as Sr, Y, La, and Lu, and mixed crystals composed of any of these elements. A mixed crystal is more preferable since the lattice constant can be optimized by doping the (TM)₂Pn₂ layers with electrons or holes. When element A has magnetic electrons, an increase in temperature Tc is obstructed; thus, rare earth metal elements having an incomplete f shell are not preferred.

In order to realize superconducting phases, the magnetic moments of the elements must be optimized so that the moments are small enough to avoid emergence of the magnetically aligned state but are as large as possible to increase magnetic fluctuations. In order to do so, at least the number of d electrons in TM must be an even number so that the spin magnetic moments of the electrons cancel one another out. In other words, for the infinite layer crystal structure of the compound that realizes the superconductor of the present invention, TM must be at least one element selected from transition metals Fe, Ru, Os, Ni, Pd, and Pt. Fe and Ni are preferred due to their adequate localization of 3d electron orbitals. Ru, Os, Pd, and Pt that have 4d and 5d electrons inhibit an increase in temperature Tc since the effective mass of electrons increases, creating heavy fermions.

Pn is at least one group 15 element of the long format periodic table selected from N, P, As, Sb, and Bi. These elements are called pnicogen elements. In N, conduction electrons tend to be localized in the (TM)Pn layers and it is difficult to raise the critical temperature. For Sb and Bi, it is necessary for chemical reactions to occur at high temperatures to obtain A(TM)₂Pn₂ and thus A(TM)₂Pn₂ is difficult to synthesize. From these points, the pnicogen element is preferably P or As. Specific examples of the compound represented by chemical formula A(TM)₂Pn₂ include BaNi₂P₂, BaFe₂As₂, SrNi₂P₂, SrNi₂As₂, and SrCu₂As₂.

Element A of the layer composed of metal bonds may be selected from at least one of group 1 elements, group 2 elements, and group 3 elements (Sc, Y, and rare earth metal elements) in the long format periodic table that are not particularly limited in terms of charges and may be combined with at least one element of a different group. For example, when a group 1 element is selected as a main constitutional element of A and some sites thereof are replaced with a group 2 element so that the dose of the group 2 element is less than 50 atomic percent, excess electrons occur and flow into the (TM)Pn layers. This means that this substitution is equivalent to doping the (TM)Pn layers with electrons. In other words, the (TM)Pn layers can be indirectly doped with electrons or holes when a combination of elements of different groups is used as element A.

When a main constitutional element of A is selected from a group 1 element, a group 2 element, and a group 3 element and an element of the same group is combined and mixed therewith, excess electrons or holes occur in the metal layers composed of element A due to the difference in electronegativity and flow into the (TM)Pn layers. Thus, the (TM)Pn in the conductive layers can be doped with electrons or holes by such mixing. For example, when group 2 elements Ca and Sr are mixed at an atomic ratio of 1:1 as the main constitutional elements of element A, excess electrons occur and some of the electrons flow into the (TM)Pn layers, thereby indirectly doping the (TM)Pn layers with electrons.

It is also possible to directly dope the (TM)Pn layers with electrons and holes by directly adding elements having different charges to the (TM)Pn layers; however, since the superconduction is derived from the (TM)Pn layers, such direct doping significantly deteriorates the superconducting properties and is thus not preferred from the viewpoint of increasing the temperature Tc.

A compound represented by chemical formula A(TM)₂Pn₂ can be synthesized by sintering a raw material powder, which has been prepared by mixing a simple substance of element A, a simple substance of element TM, a simple substance of pnicogen element, and a TM₃Pn₂ compound at an A:TM:Pn atomic ratio of 1:2:2, in vacuum or in an inert gas atmosphere at a high temperature, preferably about 700° C. to 1200° C. for a sufficient length of time so that the weight ratio of the A(TM)₂Pn₂ phase generated by the pyrogenetic reactions is about 85% or more. The resulting sintered material is constituted by grains about 10 micrometers in size and the grains are in some cases single crystals. Thus, a single crystal sample can be obtained by selectively extracting the single crystal grains from the sintered material.

For example, a sintered material can be made by vacuum-sealing in a quartz tube a powder obtained by mixing metal single materials of the constitutional elements of the A(TM)₂Pn₂ compound and a pnicogen element in chemically equivalent proportions, maintaining a temperature of 300 to 500° C., which is sufficiently lower than the melting point of the raw material, for 10 to 30 hours to allow preliminary reaction and pre-sintering, and maintaining a temperature of 700° C. to 1200° C. and more preferably 900° C. to 1000° C. for 10 to 20 hours.

In order to obtain a sintered material that has a large grain diameter and higher crystallinity within the grains, the sintered material is more preferably cooled to room temperature and crushed in vacuum or in an inert gas atmosphere to obtain powder, the powder may be pelletized using a pressing machine, and the pellets may be sintered again in vacuum or in an inert gas atmosphere by maintaining a temperature of 700° C. to 1200° C. for 10 to 20 hours. At less than 700° C., the reactions between raw materials do not proceed and the A(TM)₂Pn₂ phase is not obtained. Exceeding 1200° C., the amount of compounds of the phases other than the A(TM)₂Pn₂ phase increases, which is not preferred.

### Example 1

The present invention will now be described in detail through Examples.

### (Synthesis of BaNi₂P₂ Sintered Polycrystal Material)

Ba (product of Johnson Matthey, purity: 99.9%), P (Rare Metallic Kabushiki Kaisha, 9.9999%), and Ni (Nilaco Corporation, 99.9%) were processed into fine powders in a dry inert gas atmosphere, mixed with each other at a chemical equivalent ratio, and pressed to form pellets. The pellets were vacuum-sealed in a quartz tube and (1) fired at 400° C. for 12 hours and (2) heated to 1000° C. and maintained thereat for 12 hours to form a sintered material. The sintered material was cooled to room temperature, crushed, and pressed to form pellets, and the pellets were maintained at 1000° C. for 12 hours in vacuum to prepare a sintered material.

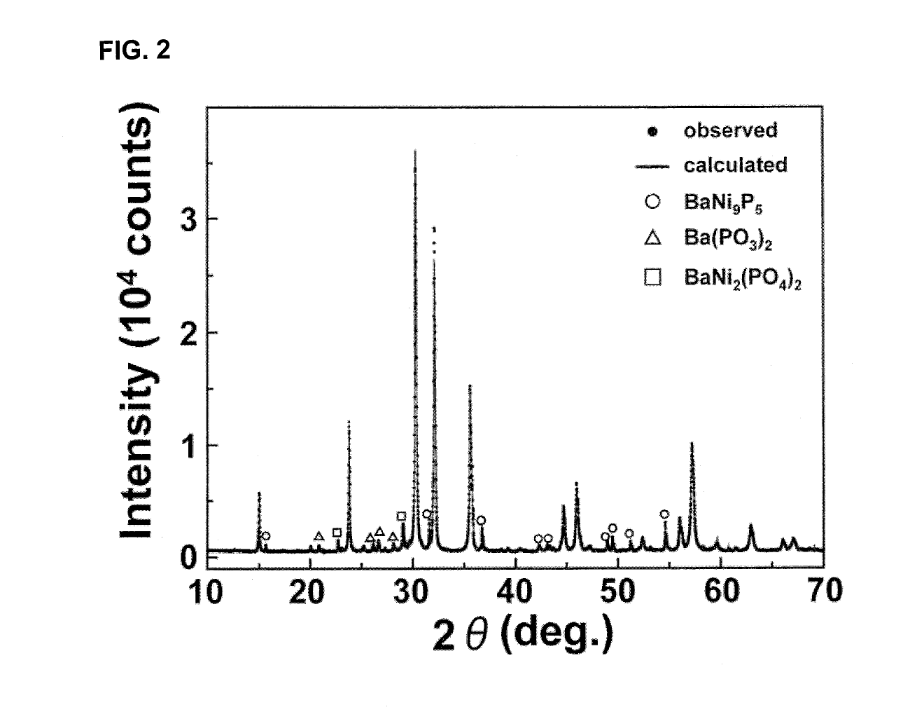

The resulting sintered material was identified as being mainly composed of BaNi₂P₂ polycrystals although trace amounts of BaNi₉P₅, Ba(PO₃)₂, and BaNi₂(PO₄)₂ were contained according to the X-ray diffraction (XRD) pattern of FIG. 2. The weight ratios of BaNi₉P₅, Ba(PO₃)₂, and BaNi₂(PO₄)₂ estimated by Rietveld analysis were 9%, 2%, and 1%, respectively.

The electrical resistance of the resulting BaNi₂P₂ sintered polycrystal material was measured within the range of 1.9 K to 300 K by a 4-terminal method using electrodes formed of a gold thin film prepared by sputtering and electrodes prepared from a silver paste. The magnetic moment was also measured in the temperature range of 1.9 to 10 K with a vibrating sample magnetometer (VSM). PPMS produced by Quantum Design Physical Inc., was used for measurement.

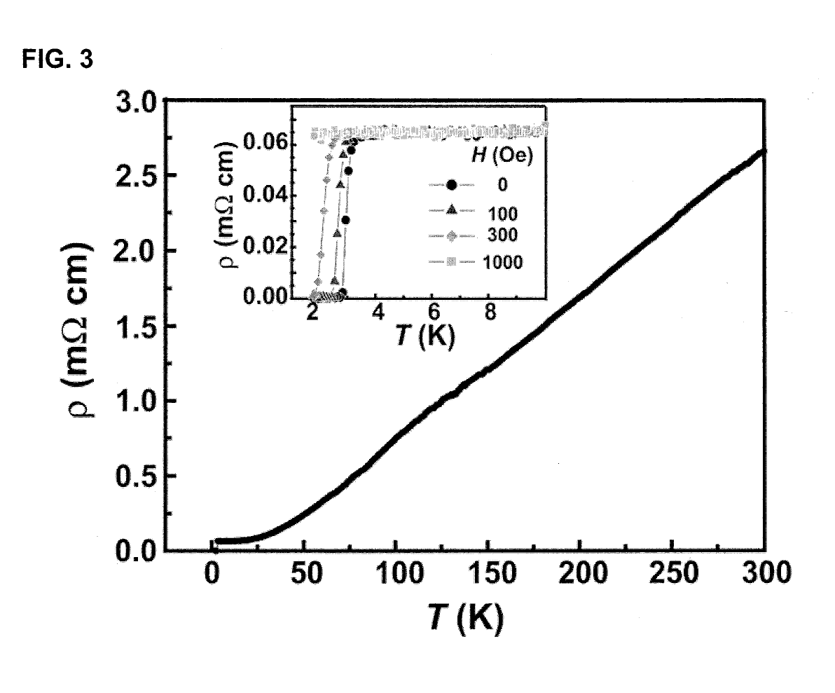

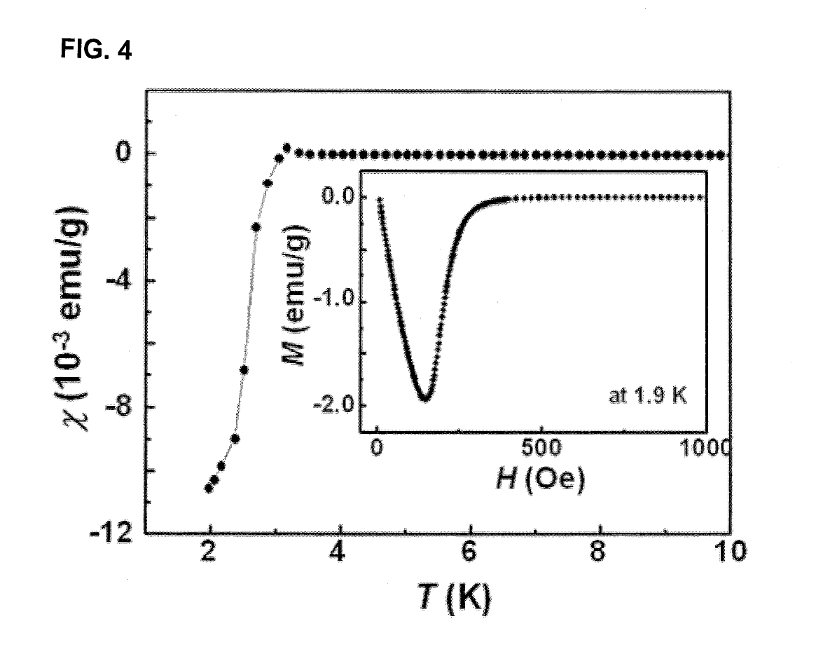

FIG. 3 is an interpolated graph showing the dependency of the electrical resistance on the magnetic field. As shown in the graph, the electrical resistance was zero at 2 to 3 T (K). FIG. 4 showing the change in magnetic susceptibility against temperature and the dependency of the magnetic moment on the magnetic field (interpolated) indicates that Tc is about 3 T (K).

### INDUSTRIAL APPLICABILITY

Compared to conventional superconductors such as copper high-temperature superconductors, the superconductor of the present invention can be easily processed into wires and can be used as a wire material for small motors and magnets.

1. A superconductor comprising a compound which is represented by chemical formula A(TM)₂Pn₂ [where A is at least one element selected from group 1 elements, group 2 elements, and group 3 elements (Sc, Y, and rare earth metals) in the long format periodic table, TM is at least one element selected from transition metal elements Fe, Ru, Os, Ni, Pd, and Pt, and Pn is at least one element selected from group 15 elements (pnicogen elements)], and which has an infinite layer crystal structure including (TM)Pn layers and metal layers of element A alternately stacked.

2. The superconductor according to claim 1, wherein A in chemical formula A(TM)₂Pn₂ is a combination of at least one element of one of group 1, group 2, and group 3 in the long format periodic table and at least one element of a different group, and (TM)Pn which forms conductive layers of the infinite layer crystal structure is doped with electrons or holes by the combination.

3. The superconductor according to claim 1, wherein A in chemical formula A(TM)₂Pn₂ is a combination of at least two elements of one of group 1, group 2, and group 3 in the long format periodic table, and (TM)Pn which forms conductive layers of the infinite layer crystal structure is doped with electrons or holes by the combination.

4. The superconductor according to claim 1, wherein in chemical formula A(TM)₂Pn₂, A is Ba, TM is Fe or Ni, and Pn is P or As.

5. The superconductor according to any one of claims 1 to 4, comprising a sintered material that contains 85% or more of a compound phase represented by chemical formula A(TM)₂Pn₂ in terms of weight ratio.

6. A process for producing the superconductor according to claim 5, comprising sintering a raw material mixed powder in vacuum or in an inert gas atmosphere at 700° C. to 1200° C.
